(19) United States
(12) Patent Application Publication
(10) Pub. No.: US 2025/0215312 A1
(43) Pub. Date: Jul. 3, 2025

(54) QUANTUM DOT AND PREPARATION METHOD THEREOF, AND LIGHT-EMITTING DEVICE

(71) Applicant: Guangdong Juhua Research Institute of Advanced Display, Guangzhou (CN)

(72) Inventors: Qiuyu LIU, Guangzhou (CN); Likuan ZHOU, Guangzhou (CN)

(73) Assignee: Guangdong Juhua Research Institute of Advanced Display, Guangzhou (CN)

(21) Appl. No.: 18/991,067

(22) Filed: Dec. 20, 2024

(30) Foreign Application Priority Data
Dec. 29, 2023 (CN) 202311873870.5

(51) Int. Cl. C09K 11/56; H10K 50/115

(52) U.S. Cl. CPC C09K 11/565; H10K 50/115

(57) ABSTRACT

The present disclosure provides a quantum dot and preparation method thereof, and a light-emitting device. In the preparation method, after forming the M1M2N1 quantum dot core, the metal element M2 second precursor is added to make the surface of the M1M2N1 quantum dot core rich with M2 cations, which may effectively reduce lattice defects and significantly improve the PLQY of the quantum dot.

This application claims priority to Chinese Application No. 202311873870.5, entitled “QUANTUM DOT AND PREPARATION METHOD THEREOF, AND LIGHT-EMITTING DEVICE”, filed on Dec. 29, 2023. The entire disclosures of the above application are incorporated herein by reference.

### TECHNICAL FIELD

The present disclosure relates to a field of quantum dot technologies, and more particularly, to a quantum dot and preparation method thereof, and a light-emitting device.

### BACKGROUND

Quantum dots (QDs) have become the most promising luminescent materials in the next generation of flat panel displays and solid-state lighting applications because of their advantages such as high fluorescence quantum yield, good monochromaticity, continuously adjustable emission spectrum with size, strong photochemical, thermal stability, and can be prepared by solution method.

However, the photoluminescence quantum yield (PLQY) of existing QDs materials still needs to be improved.

### Technical Solution

The present disclosure provides a quantum dot and preparation method thereof, and a light-emitting device, and aims to solve the problem that the photoluminescence quantum yield of the quantum dot needs to be improved.

First aspect, embodiments of the present disclosure provides a method of preparing a quantum dot including the following steps:
mixing a metal element M1 precursor, a metal element M2 first precursor and a solvent to obtain a first reaction system;
mixing a non-metallic element N1 first precursor with the first reaction system to obtain a second reaction system including an M1M2N1 quantum dot core;
mixing a metal element M2 second precursor with the second reaction system to obtain a third reaction system;
mixing a non-metallic element N1 second precursor with the third reaction system to cover an M1N1 shell layer on the surface of the M1M2N1 quantum dot core to obtain a fourth reaction system including an M1M2N1/M1N1 quantum dot. An amount of the metal element M2 second precursor is larger than an amount of the metal element M2 first precursor.

In some embodiments of the present disclosure, the step of mixing a non-metallic element N1 second precursor with the third reaction system includes: adding an amine compound to the third reaction system, reacting for a first time, then adding a non-metallic element N1 second precursor, and reacting for a second time.

In some embodiments of the present disclosure, the amine compound is a saturated or unsaturated fatty amine having 6 to 36 carbon atoms, and the amine compound is selected from at least one of oleylamine, n-octylamine, dodecylamine, tetradecylamine, and hexadecylamine.

In some embodiments of the present disclosure, a volume molar ratio of the amine compound to the metal element M1 precursor is (0.5-1) mL:(8-12) mmol.

In some embodiments of the present disclosure, the first time is 5-10 minutes.

In some embodiments of the present disclosure, the second time is 15-35 minutes.

In some embodiments of the present disclosure, the step of mixing a metal element M1 precursor, a metal element M2 first precursor and a solvent includes: mixing a metal element M1 precursor, a metal element M2 first precursor, a coordinating solvent, and a non-coordinating solvent, and then vacuum processing.

In some embodiments of the present disclosure, a molar volume ratio of the metal element M1 precursor, the metal element M2 first precursor, the coordinating solvent and the non-coordinating solvent is (8-12) mmol:(0.5-1.2) mmol:(24-48) mmol:(12-15) mL.

In some embodiments of the present disclosure, the coordinating solvent is selected from one of a C5 to C30 saturated or unsaturated fatty acid.

In some embodiments of the present disclosure, the non-coordinating solvent is selected from at least one of a C6 to C30 saturated or unsaturated aliphatic hydrocarbon, a C6 to C30 aromatic hydrocarbon, a nitrogen-containing heterocyclic compound, and a C12 to C22 aromatic ether.

In some embodiments of the present disclosure, a condition of the vacuum processing is: vacuum processing for 60-120 minutes at a reaction temperature of 120° C.-140° C.

In some embodiments of the present disclosure, a molar ratio of the metal element M2 first precursor to the non-metallic element N1 first precursor is (0.5-0.8):1.

In some embodiments of the present disclosure, a molar ratio of the non-metallic element N1 second precursor to the non-metallic element N1 first precursor is (2-3):1.

In some embodiments of the present disclosure, the step of mixing a non-metallic element N1 first precursor with the first reaction system includes: adding the non-metallic element N1 first precursor to the first reaction system at a reaction temperature of 280° C.-320° C., and then reacting for 30-60 minutes.

In some embodiments of the present disclosure, the step of mixing a metal element M2 second precursor with the second reaction system includes: adding the metal element M2 second precursor to the second reaction system, and reacting for 5-10 minutes.

In some embodiments of the present disclosure, a molar ratio of the metal element M2 second precursor to the metal element M2 first precursor is (0.05-0.1):1.

In some embodiments of the present disclosure, after obtaining the fourth reaction system including M1M2N1/M1N1 quantum dot, the method further includes: mixing a metal element M2 third precursor and a non-metallic element N2 precursor with the fourth reaction system to cover a M2N2 shell layer on the surface of the M1N1 shell layer to obtain a fifth reaction system including M1M2N1/M1N1/M2N2 quantum dot; and mixing a single molecule precursor M3 with the fifth reaction system to cover the surface of the M2N2 shell layer with an M1N2 shell layer to obtain a M1M2N1/M1N1/M2N2/M1N2 quantum dot.

In some embodiments of the present disclosure, a molar ratio of the metal element M2 third precursor to the metal element M2 first precursor is (1.5-5):1.

In some embodiments of the present disclosure, a molar ratio of the metal element M2 third precursor to the non-metallic element N2 precursor is 1:1.

In some embodiments of the present disclosure, an addition amount of the single molecule precursor M3 is 0.5-1 mmol.

In some embodiments of the present disclosure, a metal element M2 of the third precursor of the metal element M2 includes cadmium element.

In some embodiments of the present disclosure, a non-metallic element N2 of the non-metallic element N2 precursor includes at least one of sulfur element, arsenic element, tellurium element, selenium element, oxygen element, nitrogen element, phosphorus element, and antimony element.

In some embodiments of the present disclosure, the single molecule precursor M3 is selected from one of an alkyl dithioorganic acid zinc salt and S-TOP.

In some embodiments of the present disclosure, the metal element M2 third precursor is selected from at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

In some embodiments of the present disclosure, the non-metallic element N2 precursor is selected from at least one of S-TOP, S-TBP, S-TPP, S-ODE, S-OA, S-ODA, S-TOA, S-ODPA, S-OLA, S-OCA, S, alkyl mercaptans, octanethiol, decanethiol, dodecanethiol, hexadecanethiol, and mercaptopropylsilane.

In some embodiments of the present disclosure, the step of mixing a metal element M2 third precursor and a non-metallic element N2 precursor with the fourth reaction system includes: adding a metal element M2 third precursor and a non-metallic element N2 precursor to the fourth reaction system at a reaction temperature of 270° C.-290° C., and reacting for 20-40 minutes.

In some embodiments of the present disclosure, the step of mixing a single molecule precursor M3 with the fifth reaction system includes: adding a single-molecule precursor M3 to the fifth reaction system at a temperature of 200° C.-240° C., and reacting.

In some embodiments of the present disclosure, a metal element M1 of the metal element M1 precursor includes zinc element, and the metal element M1 precursor is selected from at least one of zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, zinc oleate, zinc stearate, zinc dodecanoate, zinc tetradecanoate, and zinc hexadecanoate.

In some embodiments of the present disclosure, a metal element M2 of the metal element M2 first precursor and a metal element M2 in the metal element M2 second precursor each independently includes cadmium element, and the metal element M2 first precursor and the metal element M2 second precursor is independently selected from at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

In some embodiments of the present disclosure, a non-metallic element N1 of the non-metallic element N1 first precursor and a non-metallic element N1 of the non-metallic element N1 second precursor each independently includes at least one of sulfur element, arsenic element, tellurium element, selenium element, oxygen element, nitrogen element, phosphorus element, and antimony element; and the non-metallic element N1 first precursor and the non-metallic element N1 second precursor is independently selected from at least one of Se-TOP, Se-TBP, Se-TPP, Se-ODE, Se-OA, Se-ODA, Se-TOA, Se-ODPA, Se-OLA, Se-OCA, and Se-DPP.

Second aspect, embodiments of the present disclosure further provide a quantum dot prepared by the method above.

In some embodiments of the present disclosure, the quantum dot core includes an inner core and an outer core covering the inner core, a component of the inner core is M1₁₋ₓM2ₓN1, a component of the outer core is specifically M1_{y}M2_{1-y}N1, where 0.5<x<1, 0.5<y<1, and x+y<1.

Third aspect, embodiments of the present disclosure further provide a light-emitting device, including a first electrode, a light-emitting layer, and a second electrode which are stacked. A material of the quantum dot light-emitting layer includes the quantum dot above.

The method of preparing a quantum dot provided by the present disclosure may effectively improve PLQY of quantum dot.

### BRIEF DESCRIPTION OF DRAWINGS

In order to more clearly explain the technical solutions in the embodiments of the present disclosure, the drawings to be used in the description of the embodiments are briefly described below. It is apparent that the drawings in the following description are merely some embodiments of the present disclosure. For those skilled in the art, without involving any creative effort, other drawings may be obtained based on these drawings. In the following description, the same reference numerals denote the same parts.

FIG. 1 is a flowchart of a method of preparing a quantum dot according to an embodiment of the present disclosure.

FIG. 2 is a flowchart of another method of preparing a quantum dot according to an embodiment of the present disclosure.

FIG. 3 is a schematic diagram of a light-emitting device according to an embodiment of the present disclosure;

FIG. 4 is a schematic diagram of another light-emitting device according to an embodiment of the present disclosure.

### DESCRIPTION OF REFERENCE NUMBERS

100, light-emitting device; 110, first electrode; 120, quantum dot light-emitting layer; 130, second electrode; 141, electron transport layer; 142, electron injection layer; 151, hole transport layer; 152, hole injection layer.

### DETAILED DESCRIPTION

Technical solutions in embodiments of the present disclosure will be clearly and completely described below with reference to the drawings in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure.

In the description of the present disclosure, unless stated to the contrary, location words such as “upper” and “lower” are used to specifically refer to the plane direction in the drawings. In addition, in the description of the present disclosure, the term “comprising” means “including but not limited to”. The term “exemplary” is used to mean “serving as an example, illustration, or illustration” and any embodiment described as “exemplary” is not necessarily construed as being more preferred or superior to other embodiments. The term “and/or” includes any and all combinations of one or more related listed items.

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range.

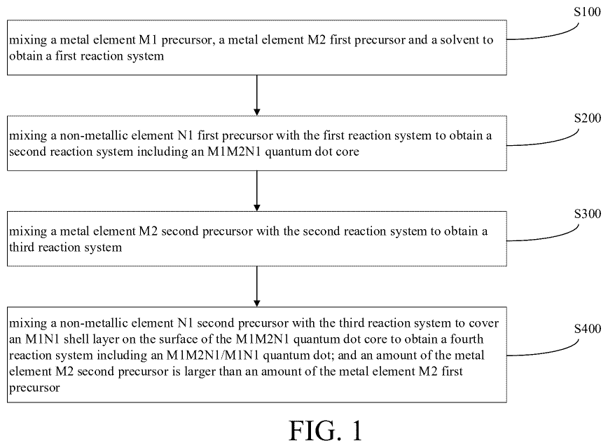

An embodiment of the present disclosure provides a method of preparing a quantum dot, referring to FIG. 1, the method includes following steps:
S100: mixing a metal element M1 precursor, a metal element M2 first precursor and a solvent to obtain a first reaction system;
S200: mixing a non-metallic element N1 first precursor with the first reaction system to obtain a second reaction system including an M1M2N1 quantum dot core;
S300: mixing a metal element M2 second precursor with the second reaction system to obtain a third reaction system;
S400: mixing a non-metallic element N1 second precursor with the third reaction system to cover an M1N1 shell layer on the surface of the M1M2N1 quantum dot core to obtain a fourth reaction system including an M1M2N1/M1N1 quantum dot; and an amount of the metal element M2 second precursor is larger than an amount of the metal element M2 first precursor.

In the method of preparing a quantum dot provided in the embodiment of the present disclosure, after forming the M1M2N1 quantum dot core, the metal element M2 second precursor is added to make the surface of the M1M2N1 quantum dot core rich with M2 cations, and then the non-metallic element N1 second precursor is added to form the M1N1 shell layer on the surface of the M1M2N1 quantum dot core; and the amount of the non-metallic element N1 second precursor is larger than that of the non-metallic element N1 first precursor, thereby forming a gradual energy level from M1M2N1 to M1N1 and a thicker M1N1 shell layer. The thicker M1N1 shell layer may passivate surface defects, and the gradual energy level from M1M2N1 to M1N1 may reduce lattice defects, thus effectively improving the PLQY of the quantum dot.

Alternatively, in the step S100, the step of mixing a metal element M1 precursor, a metal element M2 first precursor and a solvent includes: mixing a metal element M1 precursor, a metal element M2 first precursor, a coordinating solvent, and a non-coordinating solvent, and then vacuum processing. It can be understood that the reaction may be more sufficiently carried out by having the metal element M1 precursor, the metal element M2 first precursor, the coordinating solvent, and the non-coordinating solvent reacted at a temperature of 120° C.-140° C. In at least one embodiment, the metal element M1 precursor, the metal element M2 first precursor, the coordinating solvent, and the non-coordinating solvent are reacted at a reaction temperature of 120°−140° C. for 60-120 minutes.

Specifically, a condition of the vacuum processing may be: vacuum processing for 60-120 minutes (for example, 60 minutes, 70 minutes, 80 minutes, 90 minutes, 100 minutes, 110 minutes, 120 minutes, etc.) at a reaction temperature of 120° C.-140° C. (for example, 120° C., 125° C., 130° C., 135° C., or 140° C.).

In some embodiments of the present disclosure, a molar volume ratio of the metal element M1 precursor, the metal element M2 first precursor, the coordinating solvent and the non-coordinating solvent is (8-12) mmol:(0.5-1.2) mmol:(24-48) mmol:(12-15) mL, which may be specifically set according to actual needs. By adjusting the ratio of the metal element M1 precursor, the metal element M2 first precursor, the coordinating solvent, and the non-coordinating solvent, quantum dot cores of different properties may be obtained, so that the quantum dot provided in the embodiments of the present disclosure have flexible structural adjustability.

Alternatively, a metal element M1 of the metal element M1 precursor includes zinc element. In some embodiments of the present disclosure, the metal element M1 precursor may be selected from, but not limited to, at least one of zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, zinc oleate, zinc stearate, zinc dodecanoate, zinc tetradecanoate, and zinc hexadecanoate.

Alternatively, a metal element M2 of the metal element M2 first precursor includes cadmium element. In some embodiments of the present disclosure, the metal element M2 first precursor may be selected from, but not limited to, at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

Alternatively, the coordinating solvent may be selected from one of a C5 to C30 saturated or unsaturated fatty acid (i.e. a saturated or unsaturated fatty acid having 5 to 30 carbons), preferably a C8 to C20 saturated or unsaturated fatty acid (i.e. a saturated or unsaturated fatty acid having 8 to 20 carbons), for example octanoic acid, capric acid, dodecanoic acid, myristic acid, palmitic acid, stearic acid or oleic acid.

Alternatively, the non-coordinating solvent is selected from at least one of a C6 to C30 saturated or unsaturated aliphatic hydrocarbon (i.e. an aliphatic hydrocarbon having 6 to 30 carbons), a C6 to C30 aromatic hydrocarbon (i.e. an aromatic hydrocarbon having 6 to 30 carbons), a nitrogen-containing heterocyclic compound (e.g. pyridine), and a C12 to C22 aromatic ether (i.e. an aromatic ethers having 12 to 22 carbons). The C6 to C30 aliphatic hydrocarbon may be, for example, an alkane, an alkene, or an alkyne, and more specifically, hexadecane, octadecane, octadecene, squalane, and the like. The C6 to C30 aromatic hydrocarbon may be, for example, phenyldodecane, phenyltetradecane, phenylhexadecane, and the like. The C12 to C22 aromatic ether may be, for example, a phenyl ether, a benzyl ether, and the like.

In some embodiments of the present disclosure, in the step S200, the step of mixing a non-metallic element N1 first precursor with the first reaction system includes: adding the non-metallic element N1 first precursor to the first reaction system at a reaction temperature of 280° C.-320° C., and then reacting for 30-60 minutes. By setting the reaction temperature with 280° C.-320° C., it is beneficial for the nucleation reaction to better generate quantum dot core. By setting the nucleation reaction time with 30-60 minutes, it is beneficial to the state stability of the quantum dot core, so that the subsequent shell layer may grow uniformly, and at the same time, it is beneficial to improve the PLQY of the quantum dot.

For example, the non-metallic element N1 first precursor may be added to the first reaction system at a reaction temperature of 280° C., 285° C., 290° C., 295° C., 300° C., 305° C., 310° C., 315° C., or 320° C. for 30 minutes, 35 minutes, 40 minutes, 45 minutes, 50 minutes, 55 minutes, or 60 minutes to carry out a nucleation reaction. The specific reaction temperature and reaction time may be set according to actual needs.

Moreover, a molar ratio of the metal element M2 first precursor to the non-metallic element N1 first precursor may be (0.5-0.8):1, for example, 0.5:1, 0.6:1, 0.7:1, or 0.8:1, and the like. the molar ratio of the metal element M2 first precursor to the non-metallic element N1 first precursor may be specifically set according to actual needs.

Alternatively, a non-metallic element N1 of the non-metallic element N1 first precursor includes at least one of sulfur element, arsenic element, tellurium element, selenium element, oxygen element, nitrogen element, phosphorus element, and antimony element. In some embodiments of the present disclosure, the non-metallic element N1 first precursor may be selected from at least one of Se-TOP (selenium-Tri-n-octylphosphine), Se-TBP (selenium-Tributyl phosphine), Se-TPP (selenium-triphenylphosphine), Se-ODE (selenium-1-octadecene), Se-OA (selenium-oleic acid), Se-ODA (selenium-octadecylamine), Se-TOA (selenium-trioctylamine), Se-ODPA (selenium-octadecylphosphonic acid), Se-OLA (selenium-oleylamine), Se-OCA (selenium-octylamine), and Se-DPP (selenium-diphenylphosphine).

In some embodiments of the present disclosure, in the step S300, the step of mixing a metal element M2 second precursor with the second reaction system includes: adding a metal element M2 second precursor to the second reaction system, and reacting for 5-10 minutes, for example, reacting for 5 minutes, 6 minutes, 7 minutes, 8 minutes, 9 minutes, 10 minutes, and the like. The specific reaction time may be set according to actual needs.

Alternatively, a molar ratio of the metal element M2 second precursor to the metal element M2 first precursor is (0.05-0.1):1, for example, 0.05:1, 0.06:1, 0.07:1, 0.08:1, 0.09:1, 0.1:1, and the like. The molar ratio of the metal element M2 second precursor to the metal element M2 first precursor may be specifically set according to actual needs.

Alternatively, a metal element M2 of the metal element M2 second precursor includes cadmium element. In some embodiments of the present disclosure, the metal element M2 second precursor may be selected from, but not limited to, at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

In some embodiments of the present disclosure, in the step S400, a molar ratio of the non-metallic element N1 second precursor to the non-metallic element N1 first precursor is (2-3):1, for example, 2:1, 2.1:1, 2.2:1, 2.3:1, 2.3:1, 2.5:1, 2.6:1, 2.7:1, 2.8:1, 2.9:1, 3:1, and the like. The molar ratio of the non-metallic element N1 second precursor to the non-metallic element N1 first precursor may be set according to actual needs.

Alternatively, a non-metallic element N1 of the non-metallic element N1 second precursor includes at least one of sulfur element, arsenic element, tellurium element, selenium element, oxygen element, nitrogen element, phosphorus element, and antimony element. In some embodiments of the present disclosure, the non-metallic element N1 second precursor may be selected from at least one of Se-TOP (selenium-Tri-n-octylphosphine), Se-TBP (selenium-Tributyl phosphine), Se-TPP (selenium-triphenylphosphine), Se-ODE (selenium-1-octadecene), Se-OA (selenium-oleic acid), Se-ODA (selenium-octadecylamine), Se-TOA (selenium-trioctylamine), Se-ODPA (selenium-octadecylphosphonic acid), Se-OLA (selenium-oleylamine), Se-OCA (selenium-octylamine), and Se-DPP (selenium-diphenylphosphine).

In some embodiments of the present disclosure, in the step S400, the step of mixing a non-metallic element N1 second precursor with the third reaction system includes: adding an amine compound to the third reaction system, reacting for a first time, then adding a non-metallic element N1 second precursor, and reacting for a second time. Adding the amine compound is helpful to improve the activity of the metal element M1, so as to better form M1N1 shell layer and the gradual energy level from M1M2N1 quantum dot core to M1N1 shell layer.

Moreover, the amine compound is a saturated or unsaturated fatty amine having 6 to 36 carbon atoms. Preferably, the amine compound is selected from at least one of oleylamine, n-octylamine, dodecylamine, tetradecylamine, and hexadecylamine. Alternatively, a volume molar ratio of the amine compound to the metal element M1 precursor is (0.5-1) mL:(8-12) mmol, which may be specifically set according to actual needs.

Alternatively, the first time may be 5-10 minutes, for example, 5 minutes, 6 minutes, 7 minutes, 8 minutes, 9 minutes, 10 minutes, etc., and may be specifically set according to actual needs.

Alternatively, the second time may be 15-35 minutes, for example, 15 minutes, 16 minutes, 17 minutes, 18 minutes, 19 minutes, 20 minutes, 21 minutes, 22 minutes, 23 minutes, 24 minutes, 25 minutes, 26 minutes, 27 minutes, 28 minutes, 29 minutes, 30 minutes, 31 minutes, 32 minutes, 33 minutes, 34 minutes, 35 minutes, etc., and may be specifically set according to actual needs.

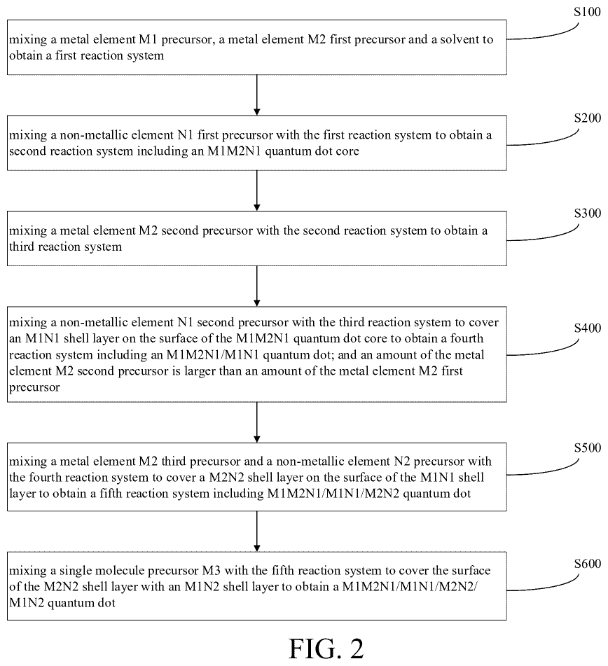

In some embodiments of the present disclosure, referring to FIG. 2, after obtaining the fourth reaction system including M1M2N1/M1N1 quantum dot, the following steps are further included:

S500: mixing a metal element M2 third precursor and a non-metallic element N2 precursor with the fourth reaction system to cover a M2N2 shell layer on the surface of the M1N1 shell layer to obtain a fifth reaction system including M1M2N1/M1N1/M2N2 quantum dot;

S600: mixing a single molecule precursor M3 with the fifth reaction system to cover the surface of the M2N2 shell layer with an M1N2 shell layer to obtain a M1M2N1/M1N1/M2N2/M1N2 quantum dot. By covering the M2N2 shell layer on the surface of the M1N1 shell layer, and covering the M1N2 shell layer on the surface of the M2N2 shell layer, the stability of the quantum dot may be improved and the PLQY decrease rate of the quantum dot may be slowed down.

Moreover, a molar ratio of the metal element M2 third precursor to the metal element M2 first precursor is (1.5-5):1, for example, 1.5:1, 2:1, 2.5:1, 3:1, 3.5:1, 4:1, 4.5:1, or 5:1, and may be specifically set according to actual needs. Alternatively, a molar ratio of the metal element M2 third precursor to the non-metallic element N2 precursor may be 1:1.

In some embodiments of the present disclosure, in the step S500, the step of mixing a metal element M2 third precursor and a non-metallic element N2 precursor with the fourth reaction system includes: adding a metal element M2 third precursor and a non-metallic element N2 precursor to the fourth reaction system at a reaction temperature of 270° C.-290° C., and reacting for 20-40 minutes. By setting the reaction temperature with 270° C.-290° C., it is beneficial to slow epitaxial growth of CdS into a high-quality shell layer, may avoid uneven epitaxial growth caused by too high temperature and too fast growth, and may avoid failure to grow caused by the temperature being too low.

For example, the reaction temperature in the step S500 may be 270° C., 275° C., 280° C., 285° C., 290° C., etc., and the reaction time in the step S500 may be 20 minutes, 21 minutes, 22 minutes, 23 minutes, 24 minutes, 25 minutes, 26 minutes, 27 minutes, 28 minutes, 29 minutes, 30 minutes, 31 minutes, 32 minutes, 33 minutes, 34 minutes, 35 minutes, 36 minutes, 37 minutes, 38 minutes, 39 minutes, or 40 minutes, etc., and may be specifically set according to actual needs.

In some embodiments of the present disclosure, in the step S600, the step of mixing a single molecule precursor M3 with the fifth reaction system includes: adding a single-molecule precursor M3 to the fifth reaction system at a temperature of 200° C.-240° C., and reacting. By setting the reaction temperature with 200° C.-240° C., it is beneficial for the single molecule to slow decomposition and epitaxial growth into a high-quality shell layer.

For example, the single molecule precursor may be added to the fifth reaction system at a reaction temperature of 200° C., 205° C., 210° C., 215° C., 220° C., 225° C., 230° C., 235° C., or 240° C.

Moreover, an addition amount of the single molecule precursor M3 may be 0.5-1 mmol, for example, 0.5 mmol, 0.6 mmol, 0.7 mmol, 0.8 mmol, 0.9 mmol, 1 mmol, etc., and may be specifically set according to actual needs. By setting the addition amount of the single molecule precursor M3 to 0.5-1 mmol, the thickness of the M1N2 shell layer may be made appropriate, which is beneficial to uniform growth and binding electrons and holes. If the thickness of the M1N2 shell layer is too thin, it is not conducive to binding electrons and holes, and if the thickness of the M1N2 shell layer is too thick, the growth will be uneven.

Alternatively, a metal element M2 of the third precursor of the metal element M2 includes cadmium element. In some embodiments of the present disclosure, the metal element M2 third precursor is selected from at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

Alternatively, a non-metallic element N2 of the non-metallic element N2 precursor includes at least one of sulfur element, arsenic element, tellurium element, selenium element, oxygen element, nitrogen element, phosphorus element, and antimony element. In some embodiments of the present disclosure, the non-metallic element N2 precursor may be selected from but not limited to at least one of S-TOP (Sulfur-Tri-n-octylphosphine), S-TBP (Sulfur-Tributyl phosphine), S-TPP (Sulfur-triphenylphosphine), S-ODE (Sulfur-1-octadecene), S-OA (Sulfur-oleic acid), S-ODA (Sulfur-octadecylamine), S-TOA (Sulfur-trioctylamine), S-ODPA (Sulfur-octadecylphosphonic acid), S-OLA (Sulfur-oleylamine), S-OCA (Sulfur-octylamine), S (triphenylphosphine), alkyl mercaptans (such as hexanethiol), octanethiol, decanethiol, dodecanethiol, hexadecanethiol, and mercaptopropylsilane.

In some embodiments of the present disclosure, the M1M2N1 quantum dot core is a ZnCdSe quantum dot core, the M1N1 shell layer is a ZnSe shell layer, and the M2N2 shell layer is a CdS shell layer. According to the band gap width, by using CdS as the second shell layer, the valence band energy level of CdS is deeper than that of the ZnCdSe quantum dot core and the first ZnSe shell layer, and the hole binding effect may be effectively improved, thereby increasing the recombination probability of electrons and holes and making light emission stronger.

The single molecule precursor M3 is selected from one of an alkyl dithioorganic acid zinc salt and S-TOP. The alkyl dithioorganic acid zinc salt includes, but not limited to, at least one of zinc bis(diethyldithiocarbamate) (CAS: 14324-55-1), zinc dialkyldithiocarbamate (CAS: 68649-42-3), and zinc dibutyldithiocarbamate (CAS: 136-23-2).

In some embodiments of the present disclosure, the M1N2 is a ZnS shell layer. The ZnS shell layer is grown by low-temperature pyrolysis using the alkyl dithioorganic acid zinc salt as a single molecule precursor. Chains of part of ligands of the quantum dot are long, the steric hindrance of part of ligands of the quantum dot is large, and the binding strength of part of ligands of the quantum dot is weak, so that the dangling bonds on the surface of the quantum dot may be passivated. In the alkyl dithioorganic acid zinc salt, chain length of S is short, steric hindrance of S is small, and binding ability of S is strong, thereby the alkyl dithioorganic acid zinc salt may passivate the uncoordinated dangling bond on the surface of the quantum dot. At the same time, the alkyl dithioorganic acid zinc salt has the characteristics of insensitivity to water and oxygen. Therefore, using the alkyl dithioorganic acid zinc salt as the single molecule precursor may effectively passivate the surface defects of the quantum dot and isolate the influence of water and oxygen, and improve the stability of quantum dots.

In some embodiments of the present disclosure, the quantum dot core of the M1M2N1/M1N1/M2N2/M1N2 quantum dot includes an inner core and an outer core covering the inner core. A component of the inner core is mainly M2N1, and a component of the inner core is specifically M1₁₋ₓM2ₓN1. A component of the outer core is mainly M1N1, and a component of the outer core is specifically M1_{y}M2_{1-y}N1. Moreover 0.5<x<1, 0.5<y<1, and x+y<1. By utilizing the difference in the activity of the precursor, the inner core is first formed and then the outer core is formed, that is, the alloying process of the inner core and the outer core is carried out separately, so the components of the quantum dot core are discontinuous, and the discontinuous structure will cause the sudden change of energy level and have better carrier binding property. By using the quantum dot provided in the present disclosure for preparing a light-emitting layer of a light-emitting device, the charge injection, the light-emitting brightness and the device efficiency of the light-emitting device may be improved.

Embodiments of the present disclosure further provides a quantum dot prepared by the above preparation method.

In some embodiments of the present disclosure, the quantum dot core of the quantum dot includes an inner core and an outer core covering the inner core. A component of the inner core is M1₁₋ₓM2ₓN1, and a component of the outer core is M1_{y}M2_{1-y}N1, where 0.5<x<1, 0.5<y<1, and x+y<1.

For example, the quantum dot is a CdZnSe/ZnSe/CdS/ZnS quantum dot, a component of the inner core of the quantum dot core CdZnSe is Zn₁₋ₓCdₓSe, and a component of the outer core of the quantum dot core CdZnSe is Zn_{y}Cd_{1-y}Se, where 0.5<x<1, 0.5<y<1, and x+y<1.

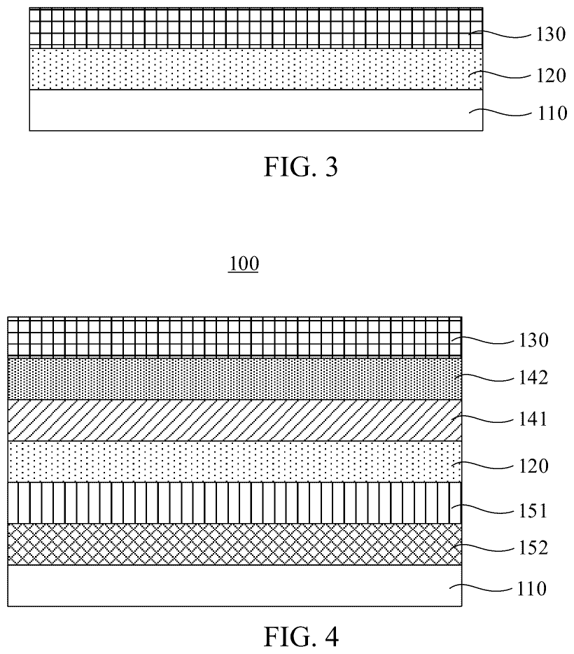

Embodiments of the present disclosure further provides a light-emitting device 100. Referring to FIG. 3, the light-emitting device 100 includes a first electrode 110, a quantum dot light-emitting layer 120, and a second electrode 130 which are stacked. A material of the quantum dot light-emitting layer 120 includes the quantum dot described in the above embodiments. Since the light-emitting device 100 adopts all the technical solutions of all the above-described embodiments, it has at least all the beneficial effects brought by the technical solutions of the above-described embodiments, and will not be repeatedly described here.

Moreover, one of the first electrode 110 and the second electrode 130 is an anode, and another is a cathode. The first electrode 110 and the second electrode 130 may be independently selected from a metal electrode, a carbon electrode, and a composite electrode formed of one or more of a doped or undoped metal oxide electrode, respectively. A material of the metal electrode is selected from at least one of Al, Ag, Cu, Mo, Au, Ba, Ca, and Mg. A material of the carbon electrode is selected from at least one of graphite, carbon nanotube, graphene, and carbon fiber. A material of the doped or undoped metal oxide electrode is selected from at least one of ITO, FTO, ATO, AZO, GZO, IZO, MZO, and AMO. A material of the composite electrode is selected from at least one of AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂, and TiO₂/Al/TiO₂.

In some embodiments of the present disclosure, the light-emitting device 100 further includes an electron transport layer 141 and an electron injection layer 142. The electron injection layer 142 is disposed between the first electrode 110 and the quantum dot light-emitting layer 120, or between the second electrode 130 and the quantum dot light-emitting layer 120. The electron transport layer 141 is disposed between the quantum dot light-emitting layer 120 and the electron injection layer 142. Specifically, referring to FIG. 4, when the first electrode 110 is the anode and the second electrode 130 is the cathode, the electron injection layer 142 is disposed between the second electrode 130 and the quantum dot light-emitting layer 120, and the electron transport layer 141 is disposed between the electron injection layer 142 and the quantum dot light-emitting layer 120. When the first electrode 110 is the cathode and the second electrode 130 is the anode, the electron injection layer 142 is disposed between the first electrode 110 and the quantum dot light-emitting layer 120, and the electron transport layer 141 is disposed between the electron injection layer 142 and the quantum dot light-emitting layer 120.

Moreover, the material of the electron transport layer 141 may be selected from, but not limited to, one or more of an inorganic electron transport material and an organic electron transport material. The inorganic electron transport material is selected from, but not limited to, one or more of a metal oxide, a doped metal oxide, a Group IIB-VIA semiconductor material, a Group IIIA-VA semiconductor material, and a Group IB-IIIA-VIA semiconductor material. Specifically, the metal oxide is selected from one or more of ZnO, TiO₂, SnO₂, Al₂O₃, Ga₂O₃, V₂O₅, V₃O₈, CrO₃, WO₃, Fe₂O₃, Fe₃O₄, CuO, MoO₂, Nb₂O₅, BaO, MoO₃, CdO, BaO, Ta₂O₅, BaTiO₃, and PbCrO₄. A metal oxide of the doped metal oxide includes one or more of ZnO, TiO₂, SnO₂, Al₂O₃, Ga₂O₃, V₂O₅, V₃O₈, CrO₃, WO₃, Fe₂O₃, Fe₃O₄, CuO, MoO₂, Nb₂O₅, BaO, MoO₃, CdO, BaO, Ta₂O₅, BaTiO₃, and PbCrO₄, and a doping element includes one or more of Al, Mg, Li, Mn, Y, La, Cu, Ni, Zr, Ce, In, Ga, and Sn. The Group IIB-VIA semiconductor material includes one or more of ZnS, ZnSe, CdS. The Group IIIB-VA semiconductor material includes one or more of InP and GaP. The Group IB-IIIB-VIA semiconductor material includes one or more of CuInS and CuGaS. The organic electron transport material includes, but not limited to, one or more of a quinoxaline compound, an imidazole compound, a triazine compound, a fluorene-containing compound, and a hydroxyquinoline compound.

Alternatively, a material of the electron injection layer 142 may be selected from one or more of LiF, MgP, MgF₂, Al₂O₃, Ga₂O₃, ZnO, Cs₂CO₃, RbBr, Rb₂CO₃, and LiF/Yb.

In some embodiments of the present disclosure, the light-emitting device 100 further includes a hole transport layer 151 and a hole injection layer 152. The hole injection layer 152 is disposed between the first electrode 110 and the quantum dot light-emitting layer 120, or between the second electrode 130 and the quantum dot light-emitting layer 120. The hole transport layer 151 is disposed between the quantum dot light-emitting layer 120 and the hole injection layer 152. Specifically, referring to FIG. 4, when the first electrode 110 is the anode and the second electrode 130 is the cathode, the hole injection layer 152 is disposed between the second electrode 130 and the quantum dot light-emitting layer 120, and the hole transport layer 151 is disposed between the hole injection layer 152 and the quantum dot light-emitting layer 120. When the first electrode 110 is the cathode and the second electrode 130 is the anode, the hole injection layer 152 is disposed between the first electrode 110 and the light-emitting layer, and the hole transport layer 151 is disposed between the hole injection layer 152 and the quantum dot light-emitting layer 120.

Moreover, a material of the hole transport layer 151 may be selected from, but not limited to, one or more of 4,4′-N,N′-dicarbazolyl-biphenyl (CBP), poly[bis(4-phenyl)(2,4,6-trimethylphenyl)amine] (PTAA), N,N′-diphenyl-N,N′-bis(1-naphthyl)-1,1′-biphenyl-4,4′-diamine (α-NPD), N,N′-diphenyl-N,N′-bis(3-methylphenyl)-(1,1′-biphenyl)-4,4′-diamine (TPD), poly(N,N′bis(4-butylphenyl)-N,N′-bis(phenyl) benzidine) (Poly-TPD), N,N′-bis(3-methylphenyl)-N,N′-bis (phenyl)-spiro (spiro-TPD), N,N′-bis(4-(N,N′-diphenyl-amino) phenyl)-N,N′-diphenylbenzidine (DNTPD), 4,4′,4′-tris (N-carbazolyl)-triphenylamine (TCTA), 4,4′,4′-tris(N-3-methylphenyl-N-phenylamino)triphenylamine (m-MTDATA), poly[(9,9′-dioctylfluorene-2,7-diyl)-co-(4,4′-dioctylfluorene-2,7-diyl)-co-(4,4′-(N-(4-sec-butylphenyl)-co-(4,4′-(N-(4-sec-butylphenyl)diphenylamine)](TFB), poly (N-vinylcarbazole) (PVK) and its derivatives, N,N′-bis(1-naphthyl)-N,N′-diphenyl-1,1′-biphenyl-4-4′-diamine (NPB), spiro NPB, poly(phenylenevinylene) (PPV), poly[2-methoxy-5-(2-ethylhexyloxy)-1,4-phenylenevinylene](MEH-PPV), poly[2-methoxy-5-(3′,7′-dimethyloctyloxy)-1,4-phenylenevinylene](MOMO-PPV), 2,2′,7,7′-tetrakis [N, N-bis(4-methoxyphenyl) amino]-9,9′-spirobifluorene (spiro-omeTAD), 4,4′-cyclohexylbis [N,N-bis(4-methylphenyl)aniline](TAPC), 1,3-bis(carbazol-9-yl)benzene (MCP), polyaniline, polypyrrole, poly(P)phenylene vinylidene, aromatic tertiary amine, polynuclear aromatic tertiary amine, 4,4′-bis(P-carbazolyl)-1,1′-biphenyl compound, N,N,N′,N′-tetraarylbenzidine, PEDOT:PSS and derivatives thereof, polymethacrylate and derivatives thereof, poly (9,9-octylfluorene) and derivatives thereof, poly (spirofluorene) and derivatives thereof, poly (spirofluorene) and derivatives thereof, doped graphene, undoped graphene, undoped graphene, C60, doped or undoped NiO, doped or undoped MoO₃, doped or undoped WO₃, doped or undoped V₂O₅, doped or undoped P type gallium nitride, doped or undoped CrO₃, and doped or undoped CuO.

Alternatively, a material of the hole injection layer 152 may be selected from, but not limited to, one or more of 2,3,6,7,10,11-hexacyano-1,4,5,8,9,12-hexaazabenzophenanthrene (HAT-CN), PEDOT, PEDOT:PSS, a derivative of PEDOT:PSS doped with s-MoO₃ (PEDOT:PSS: s-MoO₃), 4,4′,4′-tris(N-3-methylphenyl-N-phenylamino)triphenylamine (m-MTDATA), tetracyanoquinone dimethane (F4-TCQN), copper phthalocyanine, nickel oxide, molybdenum oxide, tungsten oxide, vanadium oxide, molybdenum sulfide, and copper oxide.

Hereinafter, the present disclosure will be specifically described with reference to specific examples and comparative examples, and the following examples are only partial examples of the present disclosure and do not limit the present disclosure.

### Example 1

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 0.05 mmol cadmium oleate was dropped into the three-neck flask, reacted for 5 min, and then measured that PL=638 nm, FWHM=22 nm, and PLQY=65%;
(4) 2 mmol of Se-TOP was added into the three-neck flask at a reaction temperature of 315° C., reacted for 20 min, and then measured that PL=632 nm, FWHM=21 nm, and PLQY=82%;
(5) 1.2 mmol cadmium oleate and 1.2 mmol S-TOP were added into the three-neck flask at a reaction temperature of 280° C., reacted for 30 min, and then measured that PL=632 nm, FWHM=21 nm, and PLQY=85%;
(6) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=632 nm, FWHM=21 nm, PLQY=86%.

### Example 2

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 0.05 mmol cadmium oleate was dropped into the three-neck flask, reacted for 5 min, and then measured that PL=638 nm, FWHM=22 nm, and PLQY=65%;
(4) 2.5 mmol of Se-TOP was added into the three-neck flask at a reaction temperature of 315° C., reacted for 20 min, and then measured that PL=628 nm, FWHM=21 nm, and PLQY=90%;
(5) 1.2 mmol cadmium oleate and 1.2 mmol S-TOP were added into the three-neck flask at a reaction temperature of 280° C., reacted for 30 min, and then measured that PL=627 nm, FWHM=21 nm, and PLQY=95%;
(6) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=627 nm, FWHM=21 nm, PLQY=98%.

### Example 3

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 0.05 mmol cadmium oleate was dropped into the three-neck flask, reacted for 5 min, and then measured that PL=638 nm, FWHM=22 nm, and PLQY=65%;
(4) 2 mmol of Se-TOP was added into the three-neck flask at a reaction temperature of 315° C., reacted for 20 min, and then measured that PL=625 nm, FWHM=21 nm, and PLQY=80%;
(5) 1.2 mmol cadmium oleate and 1.2 mmol S-TOP were added into the three-neck flask at a reaction temperature of 280° C., reacted for 30 min, and then measured that PL=625 nm, FWHM=21 nm, and PLQY=82%;
(6) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=625 nm, FWHM=21 nm, PLQY=83%.

### Example 4

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 0.05 mmol cadmium oleate was dropped into the three-neck flask, reacted for 5 min, and then measured that PL=638 nm, FWHM=22 nm, and PLQY=65%;
(4) 0.5 mL oleylamine was dropped into the three-neck flask and reacted for 5 min;
(5) 2 mmol of Se-TOP was added into the three-neck flask at a reaction temperature of 315° C., reacted for 20 min, and then measured that PL=632 nm, FWHM=21 nm, and PLQY=86%;
(6) 1.2 mmol cadmium oleate and 1.2 mmol S-TOP were added into the three-neck flask at a reaction temperature of 280° C., reacted for 30 min, and then measured that PL=632 nm, FWHM=21 nm, and PLQY=87%;
(7) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=632 nm, FWHM=21 nm, PLQY=88%.

### Comparative Example 1

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 0.05 mmol cadmium oleate was dropped into the three-neck flask, reacted for 5 min, and then measured that PL=638 nm, FWHM=22 nm, and PLQY=65%;
(4) 1 mmol of Se-TOP was added into the three-neck flask at a reaction temperature of 315° C., reacted for 20 min, and then measured that PL=629 nm, FWHM=22 nm, and PLQY=65%;
(5) 1.2 mmol cadmium oleate and 1.2 mmol S-TOP were added into the three-neck flask at a reaction temperature of 280° C., reacted for 30 min, and then measured that PL=629 nm, FWHM=22 nm, and PLQY=67%;
(6) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=629 nm, FWHM=22 nm, PLQY=68%.

### Comparative Example 2

A quantum dot, and a method of preparing the quantum dot includes the following steps:
(1) 0.7 mmol cadmium oleate, 10 mmol zinc oleate, 15 mL oleic acid and 15 mL ODE (octadecene) were added into a three-neck flask, vacuumed at room temperature for 20 min, then vacuumed at 80° C. for 30 min, and vacuumed at 130° C. for 60 min;
(2) the temperature was raised to 315° C. in an argon atmosphere, 1 mmol Se-TOP was quickly injected into the three-neck flask, reacted for 30 min, and then measured that PL=628 nm, FWHM=23 nm, and PLQY=30%;
(3) 2 mmol of Se-TOP was added into the three-neck flask at a reaction temperature of 315° C., reacted for 20 min, and then measured that PL=618 nm, FWHM=24 nm, and PLQY=45%;
(4) 1.2 mmol cadmium oleate and 1.2 mmol S-TOP were added into the three-neck flask at a reaction temperature of 280° C., reacted for 30 min, and then measured that PL=620 nm, FWHM=23 nm, and PLQY=50%;
(5) 1 mmol Zn(DDTC)₂ was added into the three-neck flask at a reaction temperature of 220° C., and reacted for 15 minutes, separated and purified to obtain a quantum dot CdZnSe/ZnSe/CdS/ZnS, and then measured that PL=621 nm, FWHM=24 nm, PLQY=52%.

Measuring and characterization methods in the above examples are as follows:

The cleaned quantum dot solution was measured PLQY (photoluminescence quantum yield), PL (luminescence wavelength) and FWHM (full width at half maxima) on a steady-state fluorescence spectrometer (model FS5) of Edinburgh Instruments Company in combination with a photoluminescence quantum yield accessory (model SC-30). When measuring PL and FWHM, the fluorescence excitation wavelength was 350 nm, the scanning range was 370 nm-680 nm, and the scanning speed was 2400 nm/min.

It can be seen through comparison that the PLQY of the quantum dot prepared in Example 1 to Example 3 is significantly higher than that of the quantum dot prepared in Comparative Example 1 to Comparative Example 2. The reason may be that: in the process of preparing the quantum dots in Example 1 to Example 3, after forming the CdZnSe quantum dot core, the metal element M2 second precursor cadmium oleate was added, and then the non-metallic element N1 second precursor Se-TOP was added to form a ZnSe shell layer on the surface of the CdZnSe quantum dot core, and the amount of the non-metallic element N1 second precursor Se-TOP was larger than the amount of the non-metallic element N1 second precursor Se-TOP. Thereby a gradual energy level from CdZnSe to ZnSe and a thicker ZnSe shell layer may be formed. The thicker ZnSe shell layer can passivate surface defects, and the gradual energy level from CdZnSe to ZnSe can reduce lattice defects, thus effectively improving the PLQY of the quantum dot. In Comparative Example 1, although the metal element M2 second precursor cadmium oleate was also added after forming the quantum dot core, the amount of the non-metallic element N1 second precursor Se-TOP in Comparative Example 1 was the same as that of the non-metallic element N1 second precursor Se-TOP, thereby a thicker ZnSe shell layer may not be formed. Although the amount of the non-metallic element N1 second precursor Se-TOP in Comparative Example 2 was larger than that of the non-metallic element N1 second precursor Se-TOP, the metal element M2 second precursor cadmium oleate was not added after forming the quantum dot core in Comparative Example 2, thereby the gradual energy level from CdZnSe to ZnSe may not be formed, resulting in the PLQY of the quantum dots prepared in Comparative Example 1 and Comparative Example 2 being lower than that of the quantum dots prepared in Example 1 to Example 3.

By comparing Example 1 and Example 4, it can be seen that the PLQY of the quantum dot prepared in Example 4 is higher than that of the quantum dot prepared in Example 1. The reason may be that in Example 4, oleylamine was added before the non-metallic element N1 second precursor Se-TOP was added, and oleylamine may improve the Zn activity, thus helping to better form the ZnSe shell layer and the gradual energy level from the CdZnSe quantum dot core to the ZnSe shell layer, and effectively improving the PLQY of the quantum dot.

In the above-described embodiments, the description of each embodiment has its own emphasis, and for parts not described in detail in a certain embodiment, please refer to the related description of other embodiments.

The quantum dot material and preparation method thereof, and the light-emitting diode according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. A method of preparing a quantum dot, comprising:
mixing a metal element M1 precursor, a metal element M2 first precursor and a solvent to obtain a first reaction system;
mixing a non-metallic element N1 first precursor with the first reaction system to obtain a second reaction system comprising an M1M2N1 quantum dot core;
mixing a metal element M2 second precursor with the second reaction system to obtain a third reaction system; and
mixing a non-metallic element N1 second precursor with the third reaction system to cover an M1N1 shell layer on the surface of the M1M2N1 quantum dot core to obtain a fourth reaction system comprising an M1M2N1/M1N1 quantum dot;
wherein, an amount of the metal element M2 second precursor is larger than an amount of the metal element M2 first precursor.

2. The method according to claim 1, wherein the step of mixing a non-metallic element N1 second precursor with the third reaction system comprises:
adding an amine compound to the third reaction system, reacting for a first time, then adding a non-metallic element N1 second precursor, and reacting for a second time.

3. The method according to claim 2, wherein the amine compound is a saturated or unsaturated fatty amine having 6 to 36 carbon atoms, and the amine compound is selected from at least one of oleylamine, n-octylamine, dodecylamine, tetradecylamine, and hexadecylamine;
a volume molar ratio of the amine compound to the metal element M1 precursor is (0.5-1) mL:(8-12) mmol;
the first time is 5-10 minutes; and
the second time is 15-35 minutes.

4. The method according to claim 1, wherein the step of mixing a metal element M1 precursor, a metal element M2 first precursor and a solvent comprises:
mixing a metal element M1 precursor, a metal element M2 first precursor, a coordinating solvent, and a non-coordinating solvent, and then vacuum processing.

5. The method according to claim 4, wherein a molar volume ratio of the metal element M1 precursor, the metal element M2 first precursor, the coordinating solvent and the non-coordinating solvent is (8-12) mmol:(0.5-1.2) mmol:(24-48) mmol:(12-15) mL;
the coordinating solvent is selected from one of a C5 to C30 saturated or unsaturated fatty acid;
the non-coordinating solvent is selected from at least one of a C6 to C30 saturated or unsaturated aliphatic hydrocarbon, a C6 to C30 aromatic hydrocarbon, a nitrogen-containing heterocyclic compound, and a C12 to C22 aromatic ether; and
a condition of the vacuum processing is: vacuum processing for 60-120 minutes at a reaction temperature of 120° C.-140° C.

6. The method according to claim 1, wherein a molar ratio of the metal element M2 first precursor to the non-metallic element N1 first precursor is (0.5-0.8):1;
a molar ratio of the non-metallic element N1 second precursor to the non-metallic element N1 first precursor is (2-3):1.

7. The method according to claim 1, wherein the step of mixing a non-metallic element N1 first precursor with the first reaction system comprises:
adding the non-metallic element N1 first precursor to the first reaction system at a reaction temperature of 280° C.-320° C., and then reacting for 30-60 minutes.

8. The method according to claim 1, wherein the step of mixing a metal element M2 second precursor with the second reaction system comprises:
adding a metal element M2 second precursor to the second reaction system, and reacting for 5-10 minutes.

9. The method according to claim 1, wherein a molar ratio of the metal element M2 second precursor to the metal element M2 first precursor is (0.05-0.1):1.

10. The method according to claim 1, wherein after obtaining the fourth reaction system comprising M1M2N1/M1N1 quantum dot, the method further comprises:
mixing a metal element M2 third precursor and a non-metallic element N2 precursor with the fourth reaction system to cover a M2N2 shell layer on the surface of the M1N1 shell layer to obtain a fifth reaction system comprising M1M2N1/M1N1/M2N2 quantum dot; and
mixing a single molecule precursor M3 with the fifth reaction system to cover the surface of the M2N2 shell layer with an M1N2 shell layer to obtain a M1M2N1/M1N1/M2N2/M1N2 quantum dot.

11. The method according to claim 10, wherein a molar ratio of the metal element M2 third precursor to the metal element M2 first precursor is (1.5-5):1;
a molar ratio of the metal element M2 third precursor to the non-metallic element N2 precursor is 1:1;
an addition amount of the single molecule precursor M3 is 0.5-1 mmol;
a metal element M2 of the third precursor of the metal element M2 comprises cadmium element;
a non-metallic element N2 of the non-metallic element N2 precursor comprises at least one of sulfur element, arsenic element, tellurium element, selenium element, oxygen element, nitrogen element, phosphorus element, and antimony element; and
the single molecule precursor M3 is selected from one of an alkyl dithioorganic acid zinc salt and S-TOP.

12. The method according to claim 11, wherein the metal element M2 third precursor is selected from at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate; and
the non-metallic element N2 precursor is selected from at least one of S-TOP, S-TBP, S-TPP, S-ODE, S-OA, S-ODA, S-TOA, S-ODPA, S-OLA, S-OCA, S, alkyl mercaptans, octanethiol, decanethiol, dodecanethiol, hexadecanethiol, and mercaptopropylsilane.

13. The method according to claim 11, wherein the step of mixing a metal element M2 third precursor and a non-metallic element N2 precursor with the fourth reaction system comprises:
adding a metal element M2 third precursor and a non-metallic element N2 precursor to the fourth reaction system at a reaction temperature of 270° C.-290° C., and reacting for 20-40 minutes.

14. The method according to claim 11, wherein the step of mixing a single molecule precursor M3 with the fifth reaction system comprises: adding a single-molecule precursor M3 to the fifth reaction system at a temperature of 200° C.-240° C., and reacting.

15. The method according to claim 1, wherein a metal element M1 of the metal element M1 precursor comprises zinc element, and the metal element M1 precursor is selected from at least one of zinc acetate, zinc acetylacetonate, zinc iodide, zinc bromide, zinc chloride, zinc fluoride, zinc carbonate, zinc cyanide, zinc nitrate, zinc oxide, zinc peroxide, zinc perchlorate, zinc sulfate, zinc oleate, zinc stearate, zinc dodecanoate, zinc tetradecanoate, and zinc hexadecanoate.

16. The method according to claim 1, wherein a metal element M2 of the metal element M2 first precursor and a metal element M2 in the metal element M2 second precursor each independently comprises cadmium element, and the metal element M2 first precursor and the metal element M2 second precursor is independently selected from at least one of cadmium acetate, cadmium acetylacetonate, cadmium iodide, cadmium bromide, cadmium chloride, cadmium fluoride, cadmium carbonate, cadmium nitrate, cadmium oxide, cadmium perchlorate, cadmium phosphate, cadmium sulfate, cadmium oleate, cadmium stearate, cadmium dodecanoate, cadmium tetradecanoate, and cadmium hexadecanoate.

17. The method according to claim 1, wherein a non-metallic element N1 of the non-metallic element N1 first precursor and a non-metallic element N1 of the non-metallic element N1 second precursor each independently comprises at least one of sulfur element, arsenic element, tellurium element, selenium element, oxygen element, nitrogen element, phosphorus element, and antimony element; and the non-metallic element N1 first precursor and the non-metallic element N1 second precursor is independently selected from at least one of Se-TOP, Se-TBP, Se-TPP, Se-ODE, Se-OA, Se-ODA, Se-TOA, Se-ODPA, Se-OLA, Se-OCA, and Se-DPP.

18. A quantum dot, wherein the quantum dot is prepared by the method according to claim 1.

19. The quantum dot according to claim 18, wherein the quantum dot core comprises an inner core and an outer core covering the inner core, a component of the inner core is M1₁₋ₓM2ₓN1, a component of the outer core is specifically M1_{y}M2_{1-y}N1, where 0.5<x<1, 0.5<y<1, and x+y<1.

20. A light-emitting device, comprising:
a first electrode, a light-emitting layer, and a second electrode which are stacked;
wherein a material of the quantum dot light-emitting layer comprises the quantum dot according to claim 19.
